(19) United States
(12) Patent Application Publication
(10) Pub. No.: US 2026/0088919 A1
(43) Pub. Date: Mar. 26, 2026

(54) Analytic Method of High-order Mutual Coupling Effect of Antenna Array Based on Infinitesimal Dipole Model

(71) Applicant: XIDIAN UNIVERSITY, Xi An, Shaanxi (CN)

(72) Inventors: Shunxi LOU, Xi An, Shaanxi (CN); Wei WANG, Xi An, Shaanxi (CN); Sihao QIAN, Xi An, Shaanxi (CN); Baoyan DUAN, Xi An, Shaanxi (CN); Shaofan LIAN, Xi An, Shaanxi (CN); Hong BAO, Xi An, Shaanxi (CN); Guojun LENG, Xi An, Shaanxi (CN)

(21) Appl. No.: 18/877,086

(22) PCT Filed: Mar. 21, 2024
(86) PCT No.: PCT/CN2024/082874

§ 371 Date: Dec. 19, 2024

(30) Foreign Application Priority Data
Jul. 7, 2023 (CN) 202310833334.6

(51) Int. Cl. H04B 17/391; H04B 17/20

(52) U.S. Cl. CPC H04B 17/3912; H04B 17/204

(57) ABSTRACT

The present invention discloses an analytic method of high-order mutual coupling effect of an antenna array based on infinitesimal dipole model, which comprises the following specific steps: step 1, calculating a mutual admittance between radiating elements, and constructing a mathematical relation of first-order and high-order mutual coupling effects; and step 2, establishing an admittance expression considering high-order mutual coupling effect of an N-element array. The method further improves a calculation accuracy of an antenna array radiation field by considering high-order mutual coupling effect between radiating elements.

### FIELD OF THE INVENTION

The present invention belongs to the technical field of antennas, and particularly relates to an analytic method of high-order mutual coupling effect of an antenna array based on infinitesimal dipole model.

### BACKGROUND OF THE INVENTION

The infinitesimal dipole model is a method that uses a collection of infinitesimal dipoles to equivalently simulate a target antenna. It has attracted extensive attention from researchers due to its simple principle and high-efficiency calculation. The infinitesimal dipole model can be used not only to analyze the radiation performance of a single antenna, but also to analyze and design an antenna array by equivalently simulating an radiating element. The key lies in the characterization and analysis of mutual coupling effect, which are crucial to the accurate analysis and comprehensive design of the antenna array.

Electromagnetic coupling effect exists between arbitrary two radiating elements in an antenna array, namely, the mutual coupling effect. Based on the infinitesimal dipole model, researchers have used the electromagnetic reaction theorem to calculate a self-admittance parameter of an radiating element and a mutual admittance parameter between two radiating elements in the array environment. However, most studies only considered primary electromagnetic effect of other radiating elements on the target radiating element rather than high-order effect, resulting in limited calculation accuracy of the admittance parameters. In the actual array environment, the radiating elements are often under the action of multiple electromagnetic scatterings. Therefore, exploring high-order coupling effects between the radiating elements may further improve the calculation accuracy and is of significant research importance.

### SUMMARY OF THE INVENTION

The objective of the present invention is to provide an analytic method of high-order mutual coupling effect of an antenna array based on infinitesimal dipole model, the method further improves a calculation accuracy of an antenna array radiation field by considering high-order mutual coupling effect between radiating elements.

The technical solution adopted by the present invention is as follows:

An analytic method of high-order mutual coupling effect of an antenna array based on infinitesimal dipole model, which comprises the following specific steps:
step 1, calculating a mutual admittance between radiating elements, constructing a mathematical relation of first-order and high-order mutual coupling effects, and obtaining a high-order mutual admittance relation between arbitrary two radiating elements m and n;
and step 2, according to first-order mutual coupling effect between the arbitrary two radiating elements m and n, calculating a port induced current Iₘₙ and a port induced current Iₙₘ of the arbitrary two radiating elements m and n respectively, deriving a total port current Iₘₘ and a total port current Iₙₘ of the arbitrary two radiating elements m and n respectively by considering high-order mutual coupling effect, hence obtaining a self-admittance parameter yₘₘ of the radiating element m, a mutual admittance parameter yₙₘ of the radiating element m, a self-admittance parameter yₙₙ of the radiating element n, and a mutual admittance parameter yₘₙ of the radiating element n, obtaining a relation between self-admittance and mutual admittance of the arbitrary two radiating elements m and n by calculation, and then establishing an admittance expression considering high-order mutual coupling effect of an N-element array.

Further, step 1 specifically comprises:
assuming that all radiating elements are the same, and obtaining the high-order mutual admittance relation between the arbitrary two radiating elements m and n as follows:

$${y}_{nm} = \frac{1}{{V}_{m} {V}_{n}} {\int }_{{Ω}_{n}} [ {J}_{n} \cdot {E}_{nm} - {M}_{n} \cdot {H}_{nm} ] d {Ω}_{n} \qquad ( 1 )$$

wherein, Vₘ and Vₙ denote feed port excitation voltages of the radiating elements m and n respectively in the array environment; Ωₙ denotes an integral space; an electromagnetic source (Jₙ, Mₙ) denotes a source distribution of the radiating element n in a free space; and an electromagnetic field (Eₙₘ, Hₙₘ) denotes an electromagnetic field distribution produced by the radiating element m around the radiating element n in the presence of the radiating element n.

Further, in step 2, when considering high-order mutual coupling effect, assuming that the radiating element n has a feed voltage of 0, wherein first-order mutual coupling effect indicates that the radiating element has no scattering effect, second-order mutual coupling effect indicates that the radiating element has primary scattering effect, third-order mutual coupling effect indicates that the radiating element has secondary scattering effect, and so on, so n-order mutual coupling effect indicates that the radiating element has n−1-order scattering effect.

Further, in step 2, when only first-order mutual coupling effect is considered, the mutual admittance

$${y}_{nm}^{( 1 )}$$

between the arbitrary two radiating elements m and n expressed as:

$${y}_{nm}^{( 1 )} = \frac{1}{{V}_{m} {V}_{n}} {\int }_{{Ω}_{n}} [ {J}_{n} \cdot {E}_{nm}^{( 1 )} - {M}_{n} \cdot {H}_{nm}^{( 1 )} ] d {Ω}_{n} ; \qquad ( 2 )$$

assuming that the radiating element m is fed by a constant voltage source and has a port current of Iₘ in the isolated environment, the port induced current Iₙₘ of the radiating element n is expressed as:

$${I}_{nm} = {y}_{nm}^{( 1 )} {V}_{m} = {y}_{nm}^{( 1 )} \frac{{I}_{m}}{{y}_{m}} = {α}_{nm} {I}_{m} \qquad ( 3 )$$

wherein, yₘ denotes a radiation admittance of the radiating element m in the isolated environment;
similarly, assuming that the radiating element n is fed by a constant voltage source and has a port current of Iₙ in the isolated environment, then the port induced current Iₙₘ of the radiating element m is expressed as:

$${I}_{mn} = {y}_{mn}^{( 1 )} {V}_{n} = {y}_{mn}^{( 1 )} \frac{{I}_{n}}{{y}_{n}} = {α}_{mn} {I}_{n} . \qquad ( 4 )$$

Further, in step 2, when considering high-order mutual coupling effect, assuming that the radiating element m is fed by the constant voltage source and has the port current of Iₙ in the isolated environment, and the radiating element m has a feed voltage of 0, then the total port current Iₘₘ of the radiating element m is expressed as:

$${I}_{mm} = {I}_{m} ( 1 + {α}_{mn} {α}_{nm} + {α}_{mn}^{2} {α}_{nm}^{2} + … ) = {I}_{m} \frac{1}{1 - {α}_{mn} {α}_{nm}} \qquad ( 5 )$$

the total port current Iₙₘ of the radiating element n is expressed as:

$${I}_{nm} = {I}_{m} ( {α}_{nm} + {α}_{mn} {α}_{nm}^{2} + {α}_{mn}^{2} {α}_{nm}^{2} + … ) = {I}_{m} \frac{{α}_{nm}}{1 - {α}_{mn} {α}_{nm}} \qquad ( 6 )$$

hence, the self-admittance yₘₘ of the radiating element m is expressed as:

$${y}_{mm} = \frac{{I}_{mm}}{{V}_{m}} = \frac{1}{1 - {α}_{mn} {α}_{nm}} {y}_{m} \qquad ( 7 )$$

the mutual admittance yₙₘ of the radiating element m is expressed as:

$${y}_{nm} = \frac{{I}_{nm}}{{V}_{m}} = \frac{{α}_{nm}}{1 - {α}_{mn} {α}_{nm}} {y}_{m} \qquad ( 8 )$$

similarly, when the radiating element n is fed by the constant voltage source and has the port current of Iₙ in the isolated environment, and the radiating element m has the feed voltage of 0, then the self-admittance parameter yₙₙ of the radiating element n and the mutual admittance parameter yₘₙ of the radiating element n still can be calculated according to equations (5) to (8), as shown in equations (9) and (10) below:

$${y}_{nn} = \frac{{I}_{nn}}{{V}_{n}} = \frac{1}{1 - {α}_{nm} {α}_{mn}} {y}_{n} \qquad ( 9 )$$

$${y}_{mn} = \frac{{I}_{mn}}{{V}_{n}} = \frac{{α}_{mn}}{1 - {α}_{nm} {α}_{mn}} {y}_{n} \qquad ( 10 )$$

based on the relation between self-admittance and mutual admittance of the arbitrary two radiating elements m and n in equations (7) to (10), establishing the admittance expression considering high-order mutual coupling effect of the N-element array.

Further, based on the relation between self-admittance and mutual admittance of the arbitrary two radiating elements m and n in equations (7) to (10), constructing the high-order mutual admittance relation of the N-element array, as shown below:

$${Y}_{N} = {( U - {M}_{N} {Y}_{0}^{- 1} )}^{- 1} {Y}_{0} \qquad ( 11 )$$

wherein, a matrix U is an N-order identity matrix, and a matrix M_{N} is an N-element mutual admittance matrix considering first-order mutual coupling effect; in that case, each of diagonal elements y₁₁ to yₙₘ in the matrix is 0, a matrix Y₀ is an N-element admittance matrix without considering mutual coupling effect, and a matrix element y₀ is a port input admittance of an isolated element; and
expanding equation (11) in series, and obtaining the admittance expression considering high-order mutual coupling effect of the N-element array.

Further, applying the Neumann series expansion to expand equation (11) in series, thus obtaining the admittance expression considering high-order mutual coupling effect of the N-element array, as shown below:

$${Y}_{N} = [ {\sum }_{a = 1}^{∞} {( {M}_{N} {Y}_{0}^{- 1} )}^{a} ] {Y}_{0} = {Y}_{0} + {M}_{N} + {M}_{N} {Y}_{0}^{- 1} {M}_{N} + \qquad ( 12 )$$

wherein the first term on the right-hand side of the equation is an admittance matrix without considering mutual coupling effect, the second term is a mutual admittance matrix considering first-order mutual coupling effect, the third term is a mutual admittance matrix considering second-order mutual coupling effect, and so on, thus obtaining a mathematical relation of the mutual admittance considering high-order mutual coupling effect.

Further, an expression of M_{N} in equation (12) is as follows:

$${M}_{N} = [ \begin{matrix}0 & {y}_{12}^{( 1 )} & … & {y}_{1 n}^{( 1 )} \\ {y}_{21}^{( 1 )} & 0 & … & ⋮ \\ ⋮ & ⋮ & ⋱ & {y}_{n - 1 , n}^{( 1 )} \\ {y}_{1 n}^{( 1 )} & … & {y}_{n - 1 , n}^{( 1 )} & 0\end{matrix} ] . \qquad ( 13 )$$

Further, an expression of Y₀ in equation (12) is as follows:

$${Y}_{0} = [ \begin{matrix}{y}_{0} & 0 & … & 0 \\ 0 & {y}_{0} & … & ⋮ \\ ⋮ & ⋮ & ⋱ & 0 \\ 0 & … & 0 & {y}_{0}\end{matrix} ] . \qquad ( 14 )$$

To sum up, by using the above-mentioned technical solution, the present invention has the following beneficial effects:
1. The present invention provides an analytic method of high-order mutual coupling effect of an antenna array based on infinitesimal dipole model, which starts from the definition of the first-order mutual admittance and characterizes multiple scattering effects between the radiating elements by calculating the high-order mutual admittance, and has great significance in the accurate analysis of the electrical performance of a large antenna array in practical engineering.
2. Compared with the conventional analytic method for the electrical performance of the large antenna array, the method provide by the present invention has the same accuracy as the method of moments and other full-wave methods for single-mode antennas. This is because the target antenna is equivalent to a fixed model through the infinitesimal dipole model. That is, the current distribution does not change with the influence of the incident electromagnetic field on the radiating elements. For multi-mode antenna, the method provide by the present invention can also improve analysis accuracy.

### BRIEF DESCRIPTION OF THE DRAWINGS

FIG. 1 shows a flow diagram of an analytic method of high-order mutual coupling effect of an antenna array based on infinitesimal dipole model according to the present invention;

FIG. 2 shows a schematic diagram of first-order coupling effect of a binary array;

FIG. 3 shows a schematic diagram of high-order mutual coupling effect of the binary array;

FIG. 4 shows a schematic diagram of a analysis and derivation process of high-order mutual coupling effect of the binary array;

FIG. 5 shows a schematic diagram of simulation parameters of the binary array;

FIG. 6 shows a comparison between a curve representing the variations of a self-admittance real part calculated as a function of the distance by considering first-order and high-order mutual coupling effects with the present invention and a curve obtained with the method of moments;

FIG. 7 shows a comparison between a curve representing the variations of a self-admittance imaginary part calculated as a function of the distance by considering first-order and high-order mutual coupling effects with the present invention and a curve obtained with the method of moments;

FIG. 8 shows a comparison between a curve representing the variations of a mutual admittance real part calculated as a function of the distance by considering first-order and high-order mutual coupling effects with the present invention and a curve obtained with the method of moments; and

FIG. 9 shows a comparison between a curve representing the variations of a mutual admittance imaginary part calculated as a function of the distance by considering first-order and high-order mutual coupling effects with the present invention and a curve obtained with the method of moments.

### DETAILED DESCRIPTION OF THE PREFERRED EMBODIMENTS

The present invention will be described in detail below in conjunction with the accompanying drawings.

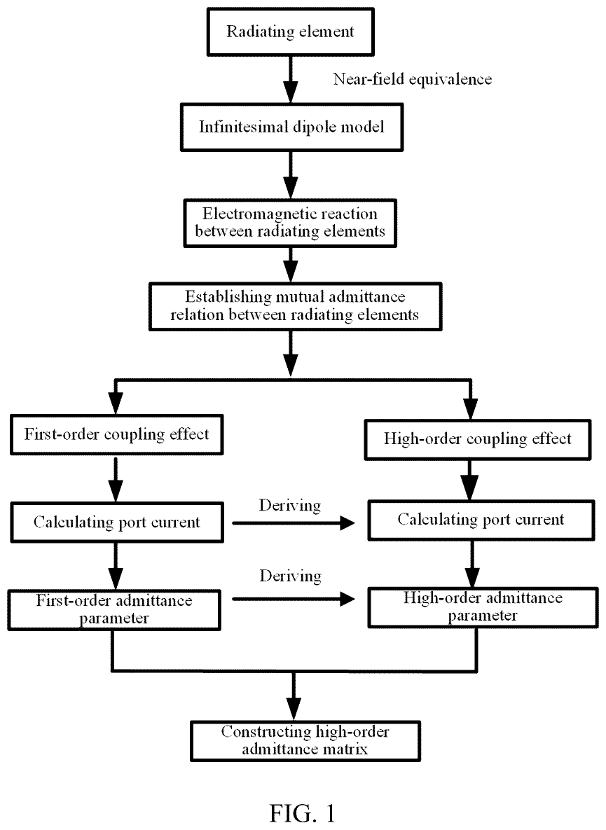

The present invention provides an analytic method of high-order mutual coupling effect of an antenna array based on infinitesimal dipole model, the analysis flow is shown in FIG. 1, and the specific steps are as follows:

Step 1, calculating a mutual admittance between radiating elements, and constructing a mathematical relation of first-order and high-order mutual coupling effects:
step 1 specifically comprises:
assuming that all radiating elements are the same, and obtaining the high-order mutual admittance relation between arbitrary two radiating elements m and n as follows:

$${y}_{nm} = \frac{1}{{V}_{m} {V}_{n}} {\int }_{{Ω}_{n}} [ {J}_{n} \cdot {E}_{nm} - {M}_{n} \cdot {H}_{nm} ] d {Ω}_{n} \qquad ( 1 )$$

wherein, Vₘ and Vₙ denote feed port excitation voltages of the radiating elements m and n respectively in the array environment; Ωₙ denotes an integral space; an electromagnetic source (Jₙ, Mₙ) denotes a source distribution of the radiating element n in a free space; and an electromagnetic field (Eₙₘ, Hₙₘ) denotes an electromagnetic field distribution produced by the radiating element m around the radiating element n in the presence (considering scattering effect) of the radiating element n (a feed port short-circuited).

Step 2, establishing an admittance expression considering high-order mutual coupling effect of the N-element array;
step 2 specifically comprises:
in substep 2.1, when only first-order mutual coupling effect is considered, the mutual admittance

$${y}_{nm}^{( 1 )}$$

between the arbitrary two radiating elements m and n is expressed as:

$${y}_{nm}^{( 1 )} = \frac{1}{{V}_{m} {V}_{n}} {\int }_{{Ω}_{n}} [ {J}_{n} \cdot {E}_{nm}^{( 1 )} - {M}_{n} \cdot {H}_{nm}^{( 1 )} ] d {Ω}_{n} \qquad ( 2 )$$

Regarding a scene with a relatively small radiating element spacing and relatively strong mutual coupling effect, it is necessary to consider high-order mutual coupling effect if the antenna performance needs to be accurately analyzed.
assuming that the radiating element m is fed by a constant voltage source and has a port current of Iₘ in the isolated environment, the port induced current Iₙₘ of the radiating element n is expressed as:

$${I}_{nm} = {y}_{nm}^{( 1 )} {V}_{m} = {y}_{nm}^{( 1 )} \frac{{I}_{m}}{{y}_{m}} = {α}_{nm} {I}_{m} \qquad ( 3 )$$

wherein, yₘ denotes a radiation admittance of the radiating element m in the isolated environment;
similarly, assuming that the radiating element n is fed by a constant voltage source and has a port current of Iₙ in the isolated environment, then the port induced current Iₙₘ of the radiating element m is expressed as:

$${I}_{mn} = {y}_{mn}^{( 1 )} {V}_{n} = {y}_{mn}^{( 1 )} \frac{{I}_{n}}{{y}_{n}} = {α}_{mn} {I}_{n} . \qquad ( 4 )$$

In substep 2.2, when considering high-order mutual coupling effect, assuming that the radiating element n has a feed voltage of 0, wherein first-order mutual coupling effect indicates that the radiating element has no scattering effect, second-order mutual coupling effect indicates that the radiating element has primary scattering effect, third-order mutual coupling effect indicates that the radiating element has secondary scattering effect, and so on, so n-order mutual coupling effect indicates that the radiating element has n−1-order scattering effect.

When considering high-order mutual coupling effect, assuming that the radiating element m is fed by the constant voltage source and has the port current of Iₙ in the isolated environment, and the radiating element m has a feed voltage of 0, then a total port current Iₘₘ of the radiating element m is expressed as:

$${I}_{mn} = {I}_{m} ( 1 + {α}_{mn} {α}_{nm} + {α}_{mn}^{2} {α}_{nm}^{2} + … ) = {I}_{m} \frac{1}{1 - {α}_{mn} {α}_{nm}} \qquad ( 5 )$$

a total port current Iₙₘ of the radiating element n is expressed as:

$${I}_{mn} = {I}_{m} ( {α}_{nm} + {α}_{mn} {α}_{nm}^{2} + {α}_{mn}^{2} {α}_{nm}^{3} + … ) = {I}_{m} \frac{{α}_{nm}}{1 - {α}_{mn} {α}_{nm}} \qquad ( 6 )$$

hence, a self-admittance yₘₘ of the radiating element m is expressed as:

$${y}_{mm} - \frac{{I}_{mm}}{{V}_{m}} - \frac{1}{1 - {α}_{mn} {α}_{nm}} {y}_{m} \qquad ( 7 )$$

a mutual admittance yₙₘ of the radiating element m is expressed as:

$${y}_{nm} = \frac{{I}_{nm}}{{V}_{m}} = \frac{{α}_{nm}}{1 - {α}_{mn} {α}_{nm}} {y}_{m} \qquad ( 8 )$$

similarly, when the radiating element n is fed by the constant voltage source and has the port current of Iₙ in the isolated environment, and the radiating element m has the feed voltage of 0, then a self-admittance parameter yₙₙ of the radiating element n and a mutual admittance parameter yₘₙ of the radiating element n still can be calculated according to the equations (5) to (8), as shown in equations (9) and (10) below:

$${y}_{nn} = \frac{{I}_{nn}}{{V}_{n}} = \frac{1}{1 - {α}_{nm} {α}_{nm}} {y}_{n} \qquad ( 9 )$$

$${y}_{mn} = \frac{{I}_{mn}}{{V}_{n}} = \frac{{α}_{mn}}{1 - {α}_{nm} {α}_{mn}} {y}_{n} \qquad ( 10 )$$

hence, according to the admittance relations of the arbitrary two radiating elements m and n in the equations (7) to (10), constructing the high-order mutual admittance relation of the N-element array, as shown below:

$${Y}_{N} = {( U - {M}_{N} {Y}_{0}^{- 1} )}^{- 1} {Y}_{0} \qquad ( 11 )$$

regarding equation (11),

$${M}_{N} = [ \begin{matrix}0 & {y}_{12}^{( 1 )} & … & {y}_{1 n}^{( 1 )} \\ {y}_{21}^{( 1 )} & 0 & … & ⋮ \\ ⋮ & ⋮ & ⋱ & {y}_{n - 1 , n}^{( 1 )} \\ {y}_{n 1}^{( 1 )} & … & {y}_{n , n - 1}^{( 1 )} & 0\end{matrix} ] . \qquad ( 12 )$$

$${Y}_{0} = [ \begin{matrix}{y}_{0} & 0 & … & 0 \\ 0 & {y}_{0} & … & ⋮ \\ ⋮ & ⋮ & ⋱ & 0 \\ 0 & … & 0 & {y}_{0}\end{matrix} ] \qquad ( 13 )$$

wherein, a matrix U is an N-order identity matrix, and a matrix M_{N} is an N-element mutual admittance matrix considering first-order mutual coupling effect; in that case, each of diagonal elements y₁₁ to yₙₙ in the matrix is 0, a matrix Y₀ is an N-element admittance matrix without considering mutual coupling effect, and a matrix element y₀ is a port input admittance of an isolated element; and as can be observed from the equations (11) to (13), an admittance matrix Y_{N} considering mutual coupling effect can be obtained from the mutual admittance matrix M_{N} considering first-order mutual coupling effect.

In substep 2.3, applying the Neumann series expansion to expand equation (11) in series, thus obtaining the admittance expression considering high-order mutual coupling effect of the N-element array, as shown below:

$${Y}_{N} = [ {{\sum }_{a = 1}}^{∞} {( {M}_{N} {Y}_{0}^{- 1} )}^{a} ] {Y}_{0} = {Y}_{0} + {M}_{N} + {M}_{N} {Y}_{0}^{- 1} {M}_{N} + … \qquad ( 14 )$$

wherein the first term on the right-hand side of the equation is an admittance matrix without considering mutual coupling effect, the second term is a mutual admittance matrix considering first-order mutual coupling effect, the third term is a mutual admittance matrix considering second-order mutual coupling effect, and so on, thus obtaining a mathematical relation of the mutual admittance considering high-order mutual coupling effect.

### Example 1

Taking a binary array as an example, the present invention is further illustrated by the following simulation case.

Step 1, a mutual admittance between radiating elements is calculated, and a mathematical relation of first-order and high-order mutual coupling effects is constructed for the binary array:

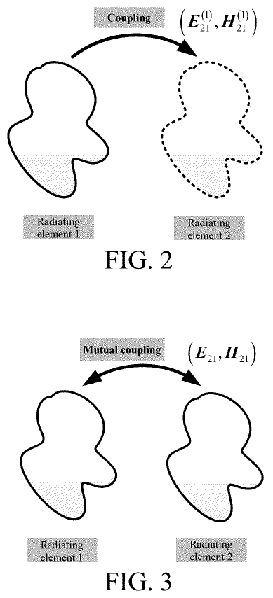

Step 1 specifically comprises:
All radiating elements of the binary array are assumed to be the same to calculate a mutual admittance between radiating elements 1 and 2. A collection of infinitesimal dipoles (J^{d}, M^{d}) are used to equivalently simulate an isolated radiating element, so that an electromagnetic near-field (E^{d}, H^{d}) produced by the radiating element and an electromagnetic near-field (E^{a}, H^{a}) produced by the collection of infinitesimal dipoles have the same distribution. According to the uniqueness theorem for electromagnetic field, the radiation far-field of the radiating element can be equivalently analyzed by use of the collection of dipoles. According to the electromagnetic reaction theorem and the electromagnetic symmetry transformation rule, a mutual admittance parameter y₂₁ between the radiating element 1 and the radiating element 2 is obtained, and the y₂₁ is specifically expressed as follows:

$${y}_{21} = \frac{1}{{V}_{1} {V}_{2}} {\int }_{{Ω}_{2}} [ {J}_{2} \cdot {E}_{21} - {M}_{2} \cdot {H}_{21} ] d {Ω}_{2} \qquad ( 15 )$$

wherein, V₁ and V₂ denote feed port excitation voltages of the radiating elements 1 and 2 respectively; Ω₂ denotes an integral space; an electromagnetic source (J₂, M₂) denotes a source distribution of the radiating element 2 in a free space; and an electromagnetic field (E₂₁, H₂₁) denotes an electromagnetic field distribution produced by the radiating element 1 around the radiating element 2 in the presence (considering scattering effect) of the radiating element 2 (a feed port short-circuited).
(2a) Taking the binary array as an example, an admittance expression considering high-order mutual coupling effect is established. Firstly, first-order coupling effect is defined. As shown in FIG. 2, due to the existence of the radiating element 2, the electromagnetic field (E₂₁, H₂₁) is different from the electromagnetic field

$$( {E}_{21}^{( 1 )} , {H}_{21}^{( 1 )} )$$

without considering scattering effect of the radiating element 2. When scattering effect of the radiating element 2 is not considered, i.e., when only first-order mutual coupling effect is considered, a mutual admittance y₂₁⁽¹⁾ is expressed as:

$${y}_{21}^{( 1 )} = \frac{1}{{V}_{1} {V}_{2}} {\int }_{{Ω}_{2}} [ {J}_{2} \cdot {E}_{21}^{( 1 )} - {M}_{2} \cdot {H}_{21}^{( 1 )} ] d {Ω}_{2} \qquad ( 16 )$$

According to the equations (15) and (16), as shown in FIG. 3, when high-order mutual coupling effect is considered, the obtained mutual admittance parameter will be different from the result obtained without considering radiating element scattering effect (first-order mutual coupling effect) (referring to FIG. 2).

Based on the above-mentioned analysis, when only first-order mutual coupling effect is considered, if the radiating element 1 is assumed to be fed by a constant voltage source and has a port current of I₁ in the isolated environment, then the port induced current I₂₁ of the radiating element 2 is expressed as:

$${I}_{21} = {y}_{21}^{( 1 )} {V}_{1} = {y}_{21}^{( 1 )} \frac{{I}_{1}}{{y}_{1}} = {α}_{21} {I}_{1} \qquad ( 17 )$$

wherein, y₁ denotes a radiation admittance of the radiating element 1 in the isolated environment. Similarly, there is

$${I}_{12} = {y}_{12}^{( 1 )} {V}_{2} = {y}_{12}^{( 1 )} \frac{{I}_{2}}{{y}_{2}} = {α}_{12} {I}_{2} \qquad ( 18 )$$

When high-order mutual coupling effect is considered, the radiating element 2 is assumed to have a feed voltage of 0, wherein first-order mutual coupling effect indicates that the radiating element has no scattering effect, second-order mutual coupling effect indicates that the radiating element has primary scattering effect, third-order mutual coupling effect indicates that the radiating element has secondary scattering effect.

When high-order mutual coupling effect is considered, a total port current I₁₁ of the radiating element 1 is expressed as:

$${I}_{11} = {I}_{1} ( 1 + {α}_{12} {α}_{21} + {α}_{12}^{2} {α}_{21}^{2} + … ) = {I}_{1} \frac{1}{1 - {α}_{12} {α}_{21}} \qquad ( 19 )$$

a total port current I₂₁ of the radiating element 2 is expressed as:

$${I}_{21} = {I}_{1} ( {α}_{21} + {α}_{12} {α}_{21}^{2} + {α}_{12}^{2} {α}_{21}^{3} + … ) = {I}_{1} \frac{{α}_{21}}{1 - {α}_{12} {α}_{21}} \qquad ( 20 )$$

hence, a self-admittance y₁₁ of the radiating element 1 is expressed as:

$${y}_{11} = \frac{{I}_{11}}{{V}_{1}} = \frac{1}{1 - {α}_{12} {α}_{21}} {y}_{1} \qquad ( 21 )$$

the mutual admittance y₂₁ of the radiating element 1 is expressed as:

$${y}_{21} = \frac{{I}_{21}}{{V}_{1}} = \frac{{α}_{21}}{1 - {α}_{12} {α}_{21}} {y}_{1} \qquad ( 22 )$$

similarly, when the radiating element 2 is fed by a constant voltage source and has a port current of I₂ in the isolated environment, and the radiating element 1 has the feed voltage of 0, then the self-admittance parameter y₂₂ of the radiating element 2 and the mutual admittance parameter y₁₂ of the radiating element 2 still can be calculated according to above-mentioned substeps (19) to (22).

$${y}_{22} = \frac{{I}_{22}}{{V}_{2}} = \frac{1}{1 - {α}_{21} {α}_{12}} {y}_{2} \qquad ( 23 )$$

$${y}_{12} = \frac{{I}_{12}}{{V}_{2}} = \frac{{α}_{12}}{1 - {α}_{21} {α}_{12}} {y}_{2} \qquad ( 24 )$$

(3a) Based on the relation between self-admittance and mutual admittance calculated with the equations (21) to (24) in (2a), an admittance matrix M₂ considering high-order mutual coupling effect for a binary array is expressed as:

$${M}_{2} = [ \begin{matrix}\frac{1}{1 - {α}_{12} {α}_{21}} & \frac{{α}_{21}}{1 - {α}_{21} {α}_{12}} \\ \frac{{α}_{21}}{1 - {α}_{12} {α}_{21}} & \frac{1}{1 - {α}_{21} {α}_{12}}\end{matrix} ] [ \begin{matrix}{y}_{1} & 0 \\ 0 & {y}_{2}\end{matrix} ] \qquad ( 25 )$$

When only the first-order coupling is considered, the above-mentioned equation degenerates into:

$${M}_{2}^{( 1 )} = [ \begin{matrix}1 + {α}_{12} {α}_{21} & {α}_{12} \\ {α}_{21} & 1 + {α}_{21} {α}_{12}\end{matrix} ] [ \begin{matrix}{y}_{1} & 0 \\ 0 & {y}_{2}\end{matrix} ] \qquad ( 26 )$$

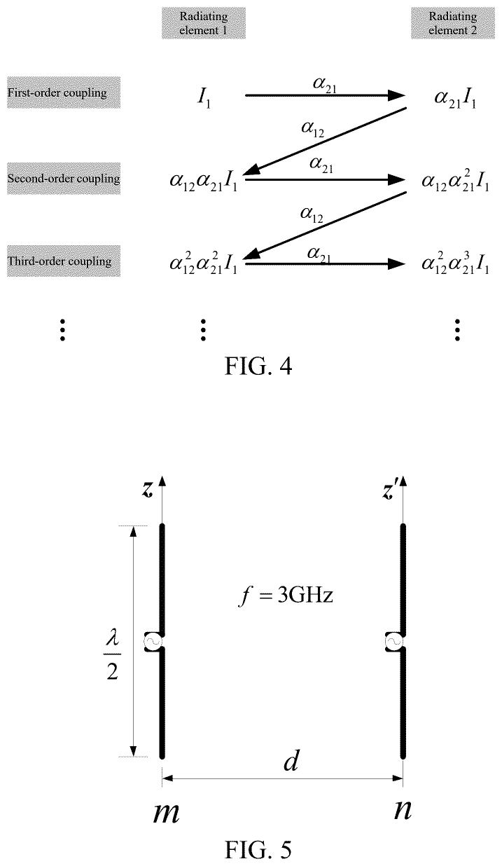

The equation is commonly used to analyze the expressions for calculating self-admittance parameters and mutual admittance parameters, the difference is that the above-mentioned equation is limited to the case of two radiating elements. FIG. 4 shows a stepwise derivation process of high-order mutual coupling effect between two radiating elements.
Accordingly, a high-order mutual admittance relation of the binary array can be constructed,

$${Y}_{2} = {( U - {M}_{2} {Y}_{0}^{′ - 1} )}^{- 1} {Y}_{0}^{′} \qquad ( 27 )$$

$${M}_{2} = [ \begin{matrix}0 & {y}_{12}^{( 1 )} \\ {y}_{21}^{( 1 )} & 0\end{matrix} ] \qquad ( 28 )$$

$${Y}_{0}^{′} = [ \begin{matrix}{y}_{0} & 0 \\ 0 & {y}_{0}\end{matrix} ] \qquad ( 29 )$$

As can be observed from the equations (25) and (26), the binary-array admittance parameters considering high-order mutual coupling effect can be expressed as the mathematical relations of the mutual admittance parameter considering first-order mutual coupling effect and the admittance parameters considering zero-order mutual coupling effect. Wherein, zero-order mutual coupling effect means that mutual coupling effect between radiating elements is not considered. That is, it is assumed that there is no electromagnetic coupling phenomenon between the elements.

The Neumann series expansion is applied to expand equation (27) in series,

$${Y}_{2} = [ {{\sum }_{a = 1}}^{∞} {( {M}_{2} {Y}_{0}^{′ - 1} )}^{a} ] {Y}_{0}^{′} = {Y}_{0}^{′} + {M}_{2} + {M}_{2} {Y}_{0}^{′ - 1} {M}_{2} + … \qquad ( 30 )$$

Hence, deriving from equation (30), the first term on the right-hand side of the equation is an admittance matrix without considering mutual coupling effect, the second term is a mutual admittance matrix considering first-order mutual coupling effect, the third term is a mutual admittance matrix considering second-order mutual coupling effect, and so on, thus a mathematical relation of the mutual admittance considering high-order mutual coupling effect can be obtained.

### 1. Simulation Parameters

Referring to FIG. 5, which shows a simulation model of a half-wave dipole element working at its center frequency f=3 GHz and a flush-mounted binary half-wave dipole array comprising the half-wave dipole element, and an radiating element spacing d varies from 0.2 times to 0.8 times the wavelength.

### 2. Simulation Content and Results

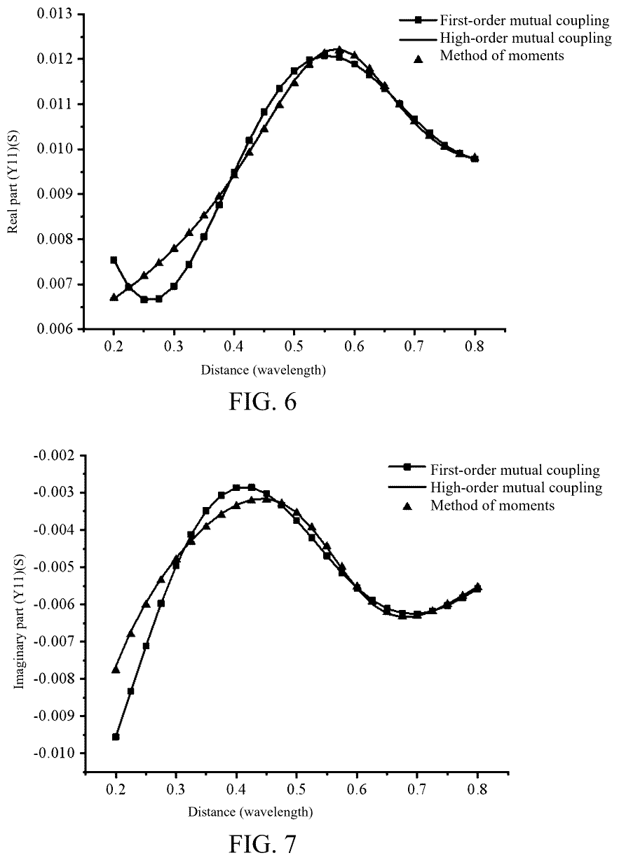

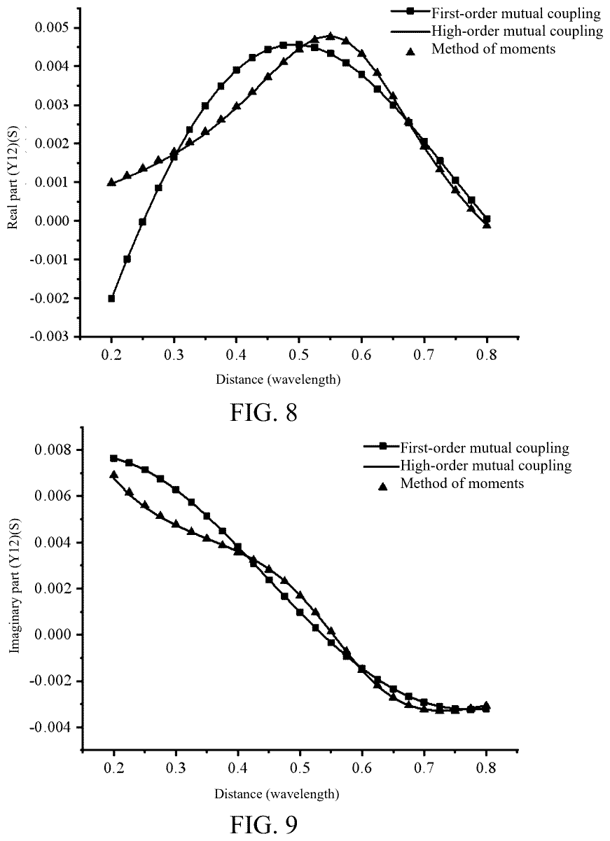

FIG. 6 shows a comparison between a curve representing the variations of a self-admittance real part calculated as a function of the distance by considering first-order and high-order mutual coupling effects and a curve obtained with the method of moments. FIG. 7 shows a comparison between a curve representing the variations of a self-admittance imaginary part calculated as a function of the distance by considering first-order and high-order mutual coupling effects and a curve obtained with the method of moments. FIG. 8 shows a comparison between a curve representing the variations of a mutual admittance real part calculated as a function of the distance by considering first-order and high-order mutual coupling effects and a curve obtained with the method of moments. FIG. 9 shows a comparison between a curve representing the variations of a mutual admittance imaginary part calculated as a function of the distance by considering first-order and high-order mutual coupling effects and a curve obtained with the method of moments.

It can be seen from FIG. 6 to FIG. 9 that in accordance with the present invention, the self-admittance and the mutual admittance calculated by considering high-order mutual coupling effect can be used for more accurately analyzing the admittance parameters of the antenna array than by considering first-order mutual coupling effect, and basically align with the analysis results of the method of moments, proving the effectiveness of the method of the present invention. Also, it can be seen from FIG. 6 to FIG. 9 that the admittance parameters can be more accurately calculated based on high-order mutual coupling effect than first-order mutual coupling effect. Table 1 shows the parameter table of infinitesimal dipoles equivalent to half-wave dipoles. Based on the position coordinates of each dipole in the table and corresponding current components, the admittance relation between arbitrary two dipoles can be calculated.

TABLE 1
Parameter Table of Infinitesimal Dipoles
Equivalent to Half-wave Dipoles

| | Position | | | |
|---|---|---|---|---|
| No. | coordinates (mm) | Iₓ(A · m) | I_{y}(A · m) | I_{z}(A · m) |
| 1 | (0, 0, 2.33) | 0 | 0 | 0.42-0.23j |
| 2 | (0, 0, 1.98) | 0 | 0 | 1.21-0.67j |
| 3 | (0, 0, 1.64) | 0 | 0 | 1.91-1.04j |
| 4 | (0, 0, 1.29) | 0 | 0 | 2.54-1.36j |
| 5 | (0, 0, 9.46) | 0 | 0 | 3.08-1.62j |
| 6 | (0, 0, 5.95) | 0 | 0 | 3.44-1.77j |
| 7 | (0, 0, 2.43) | 0 | 0 | 3.67-1.83j |
| 8 | (0, 0, 0.00) | 0 | 0 | 1.41-0.69j |
| 9 | (0, 0, −2.38) | 0 | 0 | 3.56-1.78j |
| 10 | (0, 0, −5.81) | 0 | 0 | 3.38-1.73j |
| 11 | (0, 0, −9.25) | 0 | 0 | 3.04-1.60j |
| 12 | (0, 0, −1.27) | 0 | 0 | 2.57-1.37j |
| 13 | (0, 0, −1.62) | 0 | 0 | 1.99-1.08j |
| 14 | (0, 0, −1.97) | 0 | 0 | 1.26-0.70j |
| 15 | (0, 0, −2.32) | 0 | 0 | 0.44-0.25j |

### Example 2

An analytic method of high-order mutual coupling effect of an antenna array based on infinitesimal dipole model, which comprises the following specific steps:
Step 1, a mutual admittance between radiating elements is calculated, and a mathematical relation of first-order and high-order mutual coupling effects is constructed:
Step 2, an admittance expression considering high-order mutual coupling effect is established for an N-element array.

### Example 3

An analytic method of high-order mutual coupling effect of an antenna array based on infinitesimal dipole model, which comprises the following specific steps:
Step 1, a mutual admittance between radiating elements is calculated, and a mathematical relation of first-order and high-order mutual coupling effects is constructed: step 1 specifically comprises:
all radiating elements are assumed to be the same, and the high-order mutual admittance relation between arbitrary two radiating elements m and n is obtained as follows:

$${y}_{nm} = \frac{1}{{V}_{m} {V}_{n}} {\int }_{{Ω}_{n}} [ {J}_{n} \cdot {E}_{nm} - {M}_{n} \cdot {H}_{nm} ] d {Ω}_{n} \qquad ( 1 )$$

wherein, Vₘ and Vₙ denote feed port excitation voltages of the radiating elements m and n respectively in the array environment; Ωₙ denotes an integral space; an electromagnetic source (Jₙ, Mₙ) denotes a source distribution of the radiating element n in a free space; and an electromagnetic field (Eₙₘ, Hₙₘ) denotes an electromagnetic field distribution produced by the radiating element m around the radiating element n in the presence (considering scattering effect) of the radiating element n (a feed port short-circuited).
Step 2, an admittance expression considering high-order mutual coupling effect is established for an N-element array.

What is claimed is:

1. An analytic method of high-order mutual coupling effect of an antenna array based on infinitesimal dipole model, characterized by comprising the following specific steps:
step 1, calculating a mutual admittance between radiating elements, constructing a mathematical relation of first-order and high-order mutual coupling effects, and obtaining a high-order mutual admittance relation between arbitrary two radiating elements m and n:
and step 2, according to first-order mutual coupling effect between the arbitrary two radiating elements m and n, calculating a port induced current Iₘₙ and a port induced current Iₙₘ of the arbitrary two radiating elements m and n respectively, deriving a total port current Iₘₘ and a total port current Iₙₘ of the arbitrary two radiating elements m and n respectively by considering high-order mutual coupling effect, hence obtaining a self-admittance parameter yₘₘ of the radiating element m, a mutual admittance parameter yₙₘ of the radiating element m, a self-admittance parameter yₙₙ of the radiating element n, and a mutual admittance parameter yₘₙ of the radiating element n, obtaining a relation between self-admittance and mutual admittance of the arbitrary two radiating elements m and n by calculation, and then establishing an admittance expression considering high-order mutual coupling effect of an N-element array.

2. The analytic method of high-order mutual coupling effect of an antenna array based on infinitesimal dipole model according to claim 1, characterized in that step 1 specifically comprises:
assuming that all radiating elements are the same, and obtaining the high-order mutual admittance relation between the arbitrary two radiating elements m and n as follows:
$${y}_{nm} = \frac{1}{{V}_{m} {V}_{n}} {\int }_{{Ω}_{n}} [ {J}_{n} \cdot {E}_{nm} - {M}_{n} \cdot {H}_{nm} ] d {Ω}_{n} \qquad ( 1 )$$
wherein, Vₘ and Vₙ denote feed port excitation voltages of the radiating elements m and n respectively in the array environment; Ωₙ denotes an integral space; an electromagnetic source (Jₙ, Mₙ) denotes a source distribution of the radiating element n in a free space; and an electromagnetic field (Eₙₘ, Hₙₘ) denotes an electromagnetic field distribution produced by the radiating element m around the radiating element n in the presence of the radiating element n.

3. The analytic method of high-order mutual coupling effect of an antenna array based on infinitesimal dipole model according to claim 2, characterized in that in step 2, when considering high-order mutual coupling effect, assuming that the radiating element n has a feed voltage of 0, wherein first-order mutual coupling effect indicates that the radiating element has no scattering effect, second-order mutual coupling effect indicates that the radiating element has primary scattering effect, third-order mutual coupling effect indicates that the radiating element has secondary scattering effect, and so on, so n-order mutual coupling effect indicates that the radiating element has n−1-order scattering effect.

4. The analytic method of high-order mutual coupling effect of an antenna array based on infinitesimal dipole model according to claim 3, characterized in that in step 2, when only first-order mutual coupling effect is considered, the mutual admittance
$${y}_{nm}^{( 1 )} = \frac{1}{{V}_{m} {V}_{n}} {\int }_{{Ω}_{n}} [ {J}_{n} \cdot {E}_{nm}^{( 1 )} - {M}_{n} \cdot {H}_{nm}^{( 1 )} ] d {Ω}_{n} ; \qquad ( 2 )$$
between the arbitrary two radiating elements m and n is expressed as:
$${y}_{nm}^{( 1 )}$$
assuming that the radiating element m is fed by a constant voltage source and has a port current of Iₘ in the isolated environment, the port induced current Iₙₘ of the radiating element n is expressed as:
$${I}_{nm} = {y}_{nm}^{( 1 )} {V}_{m} = {y}_{nm}^{( 1 )} \frac{{I}_{m}}{{y}_{m}} {α}_{nm} {I}_{m} \qquad ( 3 )$$
wherein, yₘ denotes a radiation admittance of the radiating element m in the isolated environment;
similarly, assuming that the radiating element n is fed by a constant voltage source and has a port current of Iₙ in the isolated environment, then the port induced current Iₙₘ of the radiating element m is expressed as:
$${I}_{mn} = {y}_{mn}^{( 1 )} {V}_{n} = {y}_{mn}^{( 1 )} \frac{{I}_{n}}{{y}_{n}} {α}_{mn} {I}_{n} . \qquad ( 4 )$$

5. The analytic method of high-order mutual coupling effect of an antenna array based on infinitesimal dipole model according to claim 4, characterized in that in step 2, when considering high-order mutual coupling effect, assuming that the radiating element m is fed by the constant voltage source and has the port current of Iₙ in the isolated environment, and the radiating element m has a feed voltage of 0, then the total port current Iₘₘ of the radiating element m is expressed as:
$${I}_{mm} = {I}_{m} ( 1 + {α}_{mn} {α}_{nm} + {α}_{mn}^{2} {α}_{nm}^{2} + … ) = {I}_{m} \frac{1}{1 - {α}_{mn} {α}_{nm}} \qquad ( 5 )$$
the total port current Iₙₘ of the radiating element n is expressed as:
$${I}_{nm} = {I}_{m} ( {α}_{nm} + {α}_{mn} {α}_{nm}^{2} + {α}_{mn}^{2} {α}_{nm}^{3} + … ) = {I}_{m} \frac{{α}_{nm}}{1 - {α}_{mn} {α}_{nm}} \qquad ( 6 )$$
hence, the self-admittance yₘₘ of the radiating element m is expressed as:
$${y}_{mm} = \frac{{I}_{mm}}{{V}_{m}} = \frac{1}{1 - {α}_{mn} {α}_{nm}} {y}_{m} \qquad ( 7 )$$
the mutual admittance yₙₘ of the radiating element m is expressed as:
$${y}_{nm} = \frac{{I}_{nm}}{{V}_{m}} = \frac{{α}_{nm}}{1 - {α}_{mn} {α}_{nm}} {y}_{m} \qquad ( 8 )$$
similarly, when the radiating element n is fed by the constant voltage source and has the port current of Iₙ in the isolated environment, and the radiating element m has the feed voltage of 0, then the self-admittance parameter yₙₙ of the radiating element n and the mutual admittance parameter yₘₙ of the radiating element n still can be calculated according to equations (5) to (8), as shown in equations (9) and (10) below:
$${y}_{nn} = \frac{{I}_{nn}}{{V}_{n}} = \frac{1}{1 - {α}_{nm} {α}_{mn}} {y}_{n} \qquad ( 9 )$$
$${y}_{mn} = \frac{{I}_{mn}}{{V}_{n}} = \frac{{α}_{mn}}{1 - {α}_{nm} {α}_{mn}} {y}_{n} \qquad ( 10 )$$
based on the relation between self-admittance and mutual admittance of the arbitrary two radiating elements m and n in equations (7) to (10), establishing the admittance expression considering high-order mutual coupling effect of the N-element array.

6. The analytic method of high-order mutual coupling effect of an antenna array based on infinitesimal dipole model according to claim 5, characterized in that based on the relation between self-admittance and mutual admittance of the arbitrary two radiating elements m and n in equations (7) to (10), constructing the high-order mutual admittance relation of the N-element array, as shown below:
$${Y}_{N} = {( U - {M}_{N} {Y}_{0}^{- 1} )}^{- 1} {Y}_{0} \qquad ( 11 )$$
wherein, a matrix U is an N-order identity matrix, and a matrix M_{N} is an N-element mutual admittance matrix considering first-order mutual coupling effect; in that case, each of diagonal elements y₁₁ to yₙₙ in the matrix is 0, a matrix Y₀ is an N-element admittance matrix without considering mutual coupling effect, and a matrix element y₀ is a port input admittance of an isolated element; and
expanding equation (11) in series, and obtaining the admittance expression considering high-order mutual coupling effect of the N-element array.

7. The analytic method of high-order mutual coupling effect of an antenna array based on infinitesimal dipole model according to claim 6, characterized by applying the Neumann series expansion to expand equation (11) in series, thus obtaining the admittance expression considering high-order mutual coupling effect of the N-element array, as shown below:
$${Y}_{N} = [ {\sum }_{a = 1}^{∞} {( {M}_{N} {Y}_{0}^{- 1} )}^{a} ] {Y}_{0} = {Y}_{0} + {M}_{N} + {M}_{N} {Y}_{0}^{- 1} {M}_{N} + … \qquad ( 12 )$$
wherein the first term on the right-hand side of the equation is an admittance matrix without considering mutual coupling effect, the second term is a mutual admittance matrix considering first-order mutual coupling effect, the third term is a mutual admittance matrix considering second-order mutual coupling effect, and so on, thus obtaining a mathematical relation of the mutual admittance considering high-order mutual coupling effect.

8. The analytic method of high-order mutual coupling effect of an antenna array based on infinitesimal dipole model according to claim 7, characterized in that an expression of M_{N} in equation (12) is as follows:
$${M}_{N} = [ \begin{matrix}0 & {y}_{12}^{( 1 )} & … & {y}_{1 n}^{( 1 )} \\ {y}_{21}^{( 1 )} & 0 & … & ⋮ \\ ⋮ & ⋮ & ⋱ & {y}_{n - 1 , n}^{( 1 )} \\ {y}_{n 1}^{( 1 )} & … & {y}_{n , n - 1}^{( 1 )} & 0\end{matrix} ] . \qquad ( 13 )$$

9. The analytic method of high-order mutual coupling effect of an antenna array based on infinitesimal dipole model according to claim 7, characterized in that an expression of Y₀ in equation (12) is as follows:
$${Y}_{0} = [ \begin{matrix}{y}_{0} & 0 & … & 0 \\ 0 & {y}_{0} & … & ⋮ \\ ⋮ & ⋮ & ⋱ & 0 \\ 0 & … & 0 & {y}_{0}\end{matrix} ] . \qquad ( 14 )$$
